(19) United States
(12) Patent Application Publication
(10) Pub. No.: US 2024/0063200 A1
(43) Pub. Date: Feb. 22, 2024

(54) HYBRID BONDING BASED INTEGRATED CIRCUIT DEVICE AND METHOD OF MANUFACTURING THE SAME

(71) Applicant: ALIBABA GROUP HOLDING LIMITED, George Town, Grand Cayman (KY)

(72) Inventors: Dimin NIU, Sunnyvale, CA (US); Shuangchen LI, Sunnyvale, CA (US); Tianchan GUAN, (US); Hongzhong ZHENG, Los Gatos, CA (US)

(21) Appl. No.: 17/754,534

(22) PCT Filed: Feb. 6, 2020
(86) PCT No.: PCT/CN2020/074397

§ 371 Date: Apr. 5, 2022

(51) Int. Cl. H01L 25/18; H01L 23/00; H10B 80/00; H01L 25/00

(52) U.S. Cl. CPC H01L 25/18; H01L 24/32; H10B 80/00; H01L 24/48; H01L 24/73; H01L 25/50; H01L 2224/32145; H01L 2224/48091; H01L 2224/48145; H01L 2224/73265; H01L 2924/1431; H01L 2924/1436; H01L 2924/1438

(57) ABSTRACT

The present disclosure relates to a hybrid bonding based integrated circuit (HBIC) device and its manufacturing method. In some embodiments, an exemplary HBIC device includes: a first die stack comprising one or more dies; and a second die stack integrated above the first die stack. The second die stack includes at least two memory dies communicatively connected to the first die stack by wire bonding.

### BACKGROUND

Electronic devices, such as tablets, computers, copiers, digital cameras, smart phones, control systems and automated teller machines, among others, often employ electronic components such as dies that are connected by various interconnect components. The dies can include memory, logic, or other integrated circuit (IC) components.

Artificial Intelligence (AI) and other machine learning applications are becoming more common and are presently in high demand. These applications need massive computational and memory abilities to train on different datasets and inference with high accuracy. Moreover, other applications like high performance computers, graphics algorithms, and the like, become more and more data and compute intensive.

### SUMMARY

In some embodiments, an exemplary hybrid bonding based integrated circuit (HBIC) device includes: a first die stack comprising one or more dies; and a second die stack integrated above the first die stack. The second die stack includes at least two memory dies communicatively connected to the first die stack by wire bonding.

In some embodiments, an exemplary method of manufacturing a hybrid bonding based integrated circuit (HBIC) device includes: forming a first die stack comprising one or more dies; forming a second die stack comprising at least two memory dies; integrating the second die stack above the first die stack; and communicatively connecting the at least two memory dies of the second die stack with a die of the first die stack by wire bonding.

In some embodiments, an exemplary terminal includes: a host unit; and a hybrid bonding based integrated circuit (HBIC) device communicatively coupled with the host unit, the HBIC device. The HBIC includes: a first die stack comprising one or more dies; and a second die stack integrated above the first die stack. The second die stack includes at least two memory dies communicatively connected to the first die stack by wire bonding.

Additional features and advantages of the present disclosure will be set forth in part in the following detailed description, and in part will be obvious from the description, or may be learned by practice of the present disclosure. The features and advantages of the present disclosure will be realized and attained by means of the elements and combinations particularly pointed out in the appended claims.

It is to be understood that the foregoing general description and the following detailed description are exemplary and explanatory only, and are not restrictive of the disclosed embodiments.

### BRIEF DESCRIPTION OF THE DRAWINGS

The accompanying drawings, which comprise a part of this specification, illustrate several embodiments and, together with the description, serve to explain the principles and features of the disclosed embodiments. In the drawings:

FIG. 1 is a schematic representation of an exemplary hybrid bonding based integrated circuit (HBIC) device, according to some embodiments of the present disclosure.

FIG. 2A is a schematic representation of a first exemplary HBIC device, according to some embodiments of the present disclosure.

FIG. 2B is a schematic representation of a second exemplary HBIC device, according to some embodiments of the present disclosure.

FIG. 2C is a schematic representation of a third exemplary HBIC device, according to some embodiments of the present disclosure.

FIG. 2D is a schematic representation of a fourth exemplary HBIC device, according to some embodiments of the present disclosure.

FIG. 2E is a schematic representation of a fifth exemplary HBIC device, according to some embodiments of the present disclosure.

FIG. 3 is a schematic representation of an exemplary die stack, according to some embodiments of the present disclosure.

FIG. 4 is a schematic representation of another exemplary die stack, according to some embodiments of the present disclosure.

FIG. 5 is a schematic representation of an exemplary HBIC device with memory dies, according to some embodiments of the present disclosure.

FIG. 6 is a schematic representation of an exemplary IC device, according to some embodiments of the present disclosure.

FIG. 7 is a flowchart of an exemplary method for manufacturing a HBIC device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems and methods consistent with aspects related to the invention as recited in the appended claims.

Today's computer environment is moving toward highly- and tightly-integrated devices. This can increase performance and reduce energy consumption. For example, process-in-memory (processing-in-memory, or processor-in-memory, hereinafter “PIM”) can perform in-storage or in-memory computation. Thus, some computations are performed closer to where data actually resides. A conventional solution involves using High Bandwidth Memory (HBM) to achieve higher bandwidth while using less power in a smaller form factor by stacking Dynamic Random Access Memory (DRAM) dies one atop another. HBM utilizes multiple through-silicon vias (TSVs) that go through all memory layers. This increases overall die overhead but have little improvement on external bandwidth.

The disclosed embodiments of the present disclosure can improve on conventional solutions such as HBM by providing, for example, a HBIC with higher energy-efficiency and lower latency.

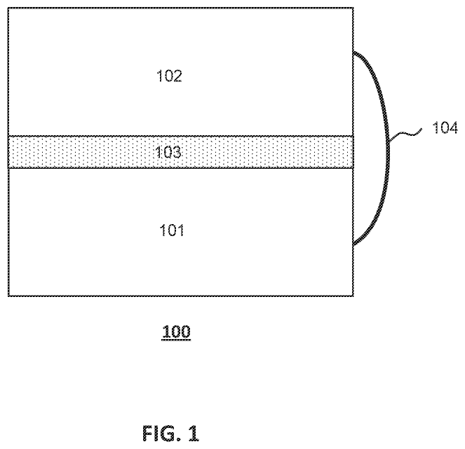

FIG. 1 is a schematic representation of an exemplary hybrid bonding based integrated circuit (HBIC) device 100, according to some embodiments of the present disclosure. As shown in FIG. 1, HBIC device 100 can include a first die stack 101, a second die stack 102, and a wire bonding 104 communicatively connecting first die stack 101 with second die stack 102. First die stack 101 can include one or more dies stacked together. Second die stack 102 can be integrated on a surface of first die stack 101, and include at least two dies stacked together. In some embodiments, two or more dies of first die stack 101 or two or more dies of second die stack 102 can be coupled or connected by various technologies, such as face-to-face integration, back-to-face integration, TSVs, contacts, metal layer, network on chip (NoC), or the like. The die in first die stack 101 or second die stack 102 can be any type of dies, including, but not limited to, logic die, memory die, storage die, PIM die, or the like. Additionally, the die in first die stack 101 or second die stack 102 can be any two-dimensional (2D) die, e.g., 2D logic die, 2D memory die, 2D storage die, 2D PIM die, or the like, or any three-dimensional (3D) die that is manufactured using a die stacking technology, e.g., 3D silicon in chip (SiC), monolithic 3D ICs, or the like. In some embodiments, the die in first die stack 101 or second die stack 102 can be implemented with DRAM process or logic process.

As shown in FIG. 1, first die stack 101 and second die stack 102 can be connected by wire bonding 104 that can communicate data and instructions between first die stack 101 and second die stack 102. Wire bonding 104 can include one or more wire connections in various topologies, such as single connection topology, bus topology, master-slave topology, multi-drop topology, or the like. One or more wire connections of wire bonding 104 can communicatively connect one or more dies of first die stack 101 with one or more dies of second die stack 102.

Optionally, HBIC device 100 can also include an interlayer 103 between first die stack 101 and second die stack 102. In some embodiments, interlayer 103 can be formed by insulating material to insulate first die stack 101 from second die stack 102. Interlayer 103 can also include metal connections therein, such as TSVs, traces, or the like. In some embodiments, interlayer 103 can include an adhesive material, such as polymer, to bond first die stack 101 with second die stack 102.

In some embodiments, HBIC device 100 can include more die stacks, such as a third die stack, a fourth die stack, . . . , etc. These die stacks can be integrated one upon another. HBIC device can also include a plurality of wire bondings. Each wire bonding can communicatively connect two or more die stacks and support communication therebetween.

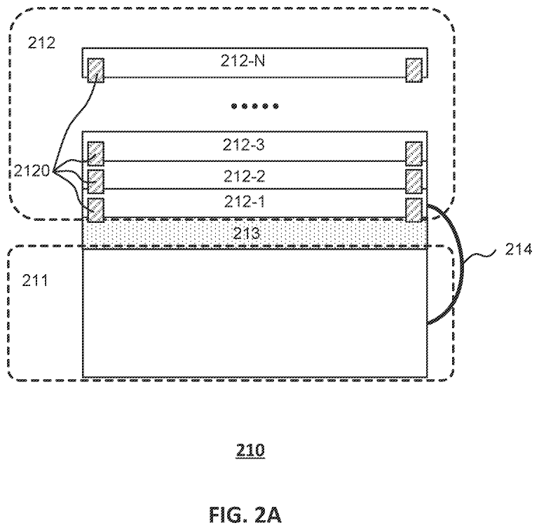

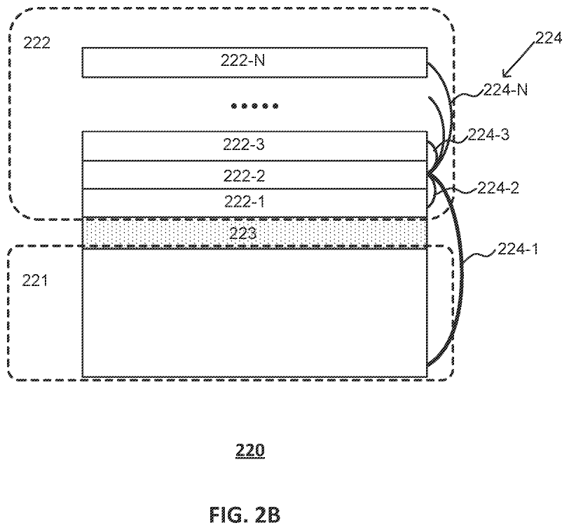

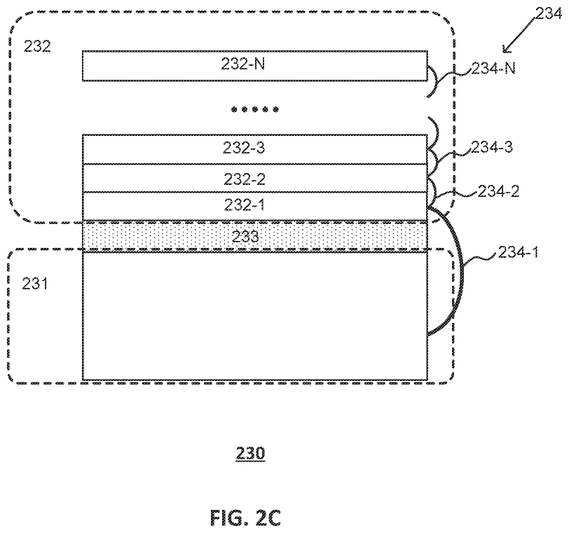

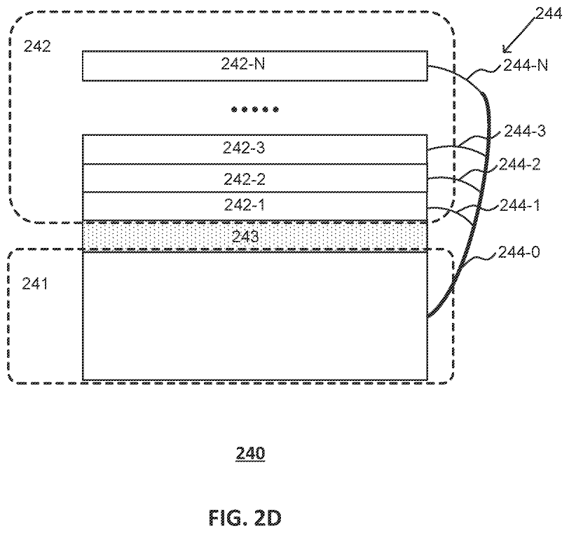

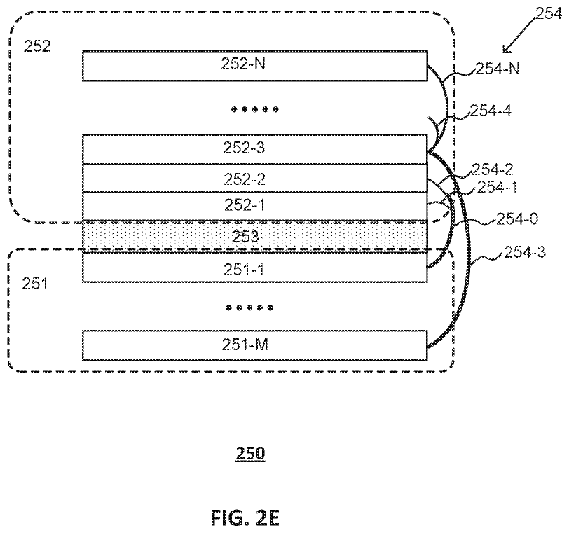

FIG. 2A is a schematic representation of a first exemplary HBIC device 210, according to some embodiments of the present disclosure. It is appreciated that, in some embodiments, HBIC device 100 of FIG. 1 can be implemented by HBIC device 210.

As shown in FIG. 2A, HBIC device 210 can include a first die stack 211 and a second die stack 212. First die stack 211 can include one or more dies stacked together. Second die stack 212 can include a plurality of dies, e.g., die 212-1, die 212-2, die 212-3, . . . , die 212-N, where N is equal to or larger than 2. Two or more dies of first die stack 211 or two or more dies of second die stack 212 can be coupled or connected by various technologies, such as face-to-face integration, back-to-face integration, TSVs, contacts, metal layer, network on chip (NoC), or the like. For example, as shown in FIG. 2A, die 212-1, die 212-2, die 212-3, . . . , die 212-N are back-to-face stacked together, and connected by a plurality of TSVs 2120. It is appreciated that the die in first die stack 211 or second die stack 212 can be any type of dies, such as 2D or 3D logic die, 2D or 3D memory die, 2D or 3D storage die, 2D or 3D PIM die, or the like.

In some embodiments, HBIC device 210 can also include an interlayer 213 between first die stack 211 and second die stack 212. Interlayer 213 can be an insulating layer, a bonding layer, the combination thereof, or the like. Interlayer 213 can include metal connections therein, such as TSVs, traces, or the like.

As shown in FIG. 2A, HBIC device 210 can include a wire bonding 214. Wire bonding 214 can connect first die stack 211 with second die stack 212, and then communicate data and instructions between first die stack 211 and second die stack 212. For example, wire bonding 214 can include a single connection topology. Wire bonding 214 can include a wire connection that communicatively connects at least one die of first die stack 211 to at least one die of second die stack 212. As shown in FIG. 2A, wire bonding 214 connects at least one die of first die stack to a die 212-1 of second die stack 212. Some of other dies of second die stack 212 can be connected to die 212-1 through multiple TSVs 2120 and thus indirectly connected to first die stack 211. In some embodiments, wire bonding 214 includes a plurality of wire connections, and second die stack 212 can include multiple groups of dies. Each connection can communicatively connect one or more dies of first die stack 211 with a group of dies of second die stack 212. In each group, dies can be connected and communicate with each other, such as through TSVs 2120.

FIG. 2B is a schematic representation of a second exemplary HBIC device 220, according to some embodiments of the present disclosure. It is appreciated that, in some embodiments, HBIC device 100 of FIG. 1 can be implemented by HBIC device 220.

Similar to HBIC device 210 of FIG. 2A, as shown in FIG. 2B, HBIC device 220 can include a first die stack 221 of one or more dies, and a second die stack 222 of a plurality of dies, e.g., die 222-1, die 222-2, die 222-3, . . . , die 222-N, where N is equal to or larger than 2. Two or more dies of first die stack 221 or two or more dies of second die stack 222 can be coupled or connected by various technologies, such as face-to-face integration, back-to-face integration, TSVs, contacts, metal layer, network on chip (NoC), or the like. For example, as shown in FIG. 2B, die 222-1, die 222-2, die 222-3, . . . , die 222-N are back-to-face stacked together. It is appreciated that, the die in first die stack 221 or second die stack 222 can be any type of dies, such as 2D or 3D logic die, 2D or 3D memory die, 2D or 3D storage die, 2D or 3D PIM die, or the like. Optionally, in some embodiments, HBIC device 220 can also include an interlayer 223 between first die stack 221 and second die stack 222.

As shown in FIG. 2B, HBIC device 220 can include a wire bonding 224. Wire bonding 224 can connect first die stack 221 with second die stack 222 and then, communicate data and instructions between first die stack 221 and second die stack 222. For example, wire bonding 224 can include a master-slave topology. As shown in FIG. 2B, wire bonding 224 can include a plurality of wire connections, e.g., wire connection 224-1, wire connection 224-2, wire connection 224-3, . . . , wire connection 224-N. Wire connection 224-1 can connect at least one die of first die stack 221 to a master die 222-1 of second die stack 222. Wire connection 224-2, wire connection 224-3, . . . , wire connection 224-N can connect master die 222-1 to slave die 222-2, slave die 222-3, . . . , slave die 222-N, respectively. For example, in some embodiments, master die 222-1 is a logic die, and slave dies 222-2, 222-3, . . . , 222-N are memory dies. Master logic die 222-1 can function as a controller that receives instructions or data from first die stack, and controls data or instruction access (e.g., read or write) to each of slave memory dies 222-2, 222-3, . . . , 222-N. Master logic die 222-1 can also perform some computations with data from slave memory dies 222-2, 222-3, . . . , 222-N, and output the computation result to first die stack 221. In some embodiments, wire connection 224-1 to the master die can be a high-speed and high-bandwidth connection, while wire connections 224-2, 224-3, . . . , 224-N can be relatively low-speed and low bandwidth connections.

FIG. 2C is a schematic representation of a third exemplary HBIC device 230, according to some embodiments of the present disclosure. It is appreciated that, in some embodiments, HBIC device 100 of FIG. 1 can be implemented by HBIC device 230.

Similar to HBIC device 210 of FIG. 2A or HBIC device 220 of FIG. 2B, as shown in FIG. 2C, HBIC device 230 can include a first die stack 231 of one or more dies, and a second die stack 232 of a plurality of dies, e.g., die 232-1, die 232-2, die 232-3, . . . , die 232-N, where N is equal to or larger than 2. Two or more dies of first die stack 231 or two or more dies of second die stack 232 can be coupled or connected by various technologies, such as face-to-face integration, back-to-face integration, TSVs, contacts, metal layer, network on chip (NoC), or the like. For example, as shown in FIG. 2C, die 232-1, die 232-2, die 232-3, . . . , die 232-N are back-to-face stacked together. It is appreciated that, the die in first die stack 231 or second die stack 232 can be any type of dies, such as 2D or 3D logic die, 2D or 3D memory die, 2D or 3D storage die, 2D or 3D PIM die, or the like. Optionally, in some embodiments, HBIC device 230 can also include an interlayer 233 between first die stack 231 and second die stack 232.

As shown in FIG. 2C, HBIC device 230 can include a wire bonding 234 that can connect first die stack 231 with second die stack 232 and communicate data and instructions between first die stack 231 and second die stack 232. As shown in FIG. 2C, wire bonding 234 can include a multi-drop topology. For example, wire bonding 234 can include a plurality of wire connections, e.g., wire connection 234-1, wire connection 234-2, wire connection 234-3, . . . , wire connection 234-N. Wire connection 234-1 can connect at least one die of first die stack 231 to a first die 232-1 of second die stack 232. Wire connection 234-2 can connect first die 232-1 to a second die 232-2, wire connection 234-3 can connect second die 232-2 to a third die 232-3, . . . , wire connection 234-N can connect a (N−1)th die 232-(N−1) to Nth die 232-N. In multi-drop topology, wire bonding 234 can communicatively connect first die stack 231, through multiple drops, to a plurality of dies in second die stack 232. Then, wire bonding 234 can communicate data and instructions between first die stack 231 and second die stack 232 through a plurality of wire connections with multiple drops to dies of second die stack 232. In some embodiments, wire connection 234-1 can be a high-speed and high-bandwidth connection, while wire connections 234-2, 234-3, . . . , 234-N can be relatively low-speed and low bandwidth connections.

FIG. 2D is a schematic representation of a fourth exemplary HBIC device 240, according to some embodiments of the present disclosure. It is appreciated that, in some embodiments, HBIC device 100 of FIG. 1 can be implemented by HBIC device 240.

Similar to HBIC device 210 of FIG. 2A, HBIC device 220 of FIG. 2B, or HBIC device 230 of FIG. 2C, as shown in FIG. 2D, HBIC device 240 can include a first die stack 241 of one or more dies, and a second die stack 242 of a plurality of dies, e.g., die 242-1, die 242-2, die 242-3, . . . , die 242-N, where N is equal to or larger than 2. Two or more dies of first die stack 241 or two or more dies of second die stack 242 can be coupled or connected by various technologies, such as face-to-face integration, back-to-face integration, TSVs, contacts, metal layer, network on chip (NoC), or the like. For example, as shown in FIG. 2D, die 242-1, die 242-2, die 242-3, . . . , die 242-N are back-to-face stacked together. It is appreciated that, the die in first die stack 241 or second die stack 242 can be any type of dies, such as 2D or 3D logic die, 2D or 3D memory die, 2D or 3D storage die, 2D or 3D PIM die, or the like. Optionally, in some embodiments, HBIC device 240 can also include an interlayer 243 between first die stack 241 and second die stack 242.

As shown in FIG. 2D, HBIC device 240 can include a wire bonding 244 that can connect first die stack 241 with second die stack 242 and communicate data and instructions between first die stack 241 and second die stack 242. As shown in FIG. 2D, wire bonding 244 can include a shared bus topology. For example, wire bonding 244 can include a bus, e.g., a bus 244-0, and a plurality of wire connections connected to the bus, e.g., wire connection 244-1, wire connection 244-2, wire connection 244-3, . . . , wire connection 244-N. Bus 244-0 can extend from at least one die of first die stack 241 to second die stack 242. Wire connection 244-1, wire connection 244-2, wire connection 244-3, . . . , wire connection 244-N, can connect bus 244-0 and thus first die stack 241 to die 242-1, die 242-2, die 242-3, . . . , die 242-N of second die stack 242, respectively. Each connected die 242-N of second die stack 242 can share bandwidth of bus 244-0, and communicate with first die stack through its corresponding wire connection 244-n and bus 244-0. In some embodiments, bus 244-0 can be an address/command bus. In some embodiments, bus 244-0 can be a high-speed and high-bandwidth connection, while wire connections 244-1, 244-2, 244-3, . . . , 244-N can be relatively low-speed and low bandwidth connections.

It is appreciated that although FIGS. 2A-2D each illustrates an exemplary connection topology of wire bonding (e.g., wire bonding 214 of FIG. 2A, wire bonding 224 of FIG. 2B, wire bonding 234 of FIG. 2C, or wire bonding 244 of FIG. 2D), wire bonding can include other types of topologies, such as die-to-die wire connection, or the like. In some embodiments, wire bonding can include a combination of different topologies.

FIG. 2E is a schematic representation of a fifth exemplary HBIC device 250, according to some embodiments of the present disclosure. It is appreciated that, in some embodiments, HBIC device 100 of FIG. 1 can be implemented by HBIC device 250.

Similar to HBIC device 210 of FIG. 2A, HBIC device 220 of FIG. 2B, HBIC device 230 of FIG. 2C, or HBIC device 240 of FIG. 2D, as shown in FIG. 2E, HBIC device 250 can include a first die stack 251 of a plurality of dies, e.g., die 251-1, . . . , die 251-M, where M is equal to or larger than 2, and a second die stack 252 of a plurality of dies, e.g., die 252-1, die 252-2, die 252-3, . . . , die 252-N, where N is equal to or larger than 2. Two or more dies of first die stack 251 or two or more dies of second die stack 252 can be coupled or connected by various technologies, such as face-to-face integration, back-to-face integration, TSVs, contacts, metal layer, network on chip (NoC), or the like. It is appreciated that the die in first die stack 251 or second die stack 252 can be any type of dies, such as 2D or 3D logic die, 2D or 3D memory die, 2D or 3D storage die, 2D or 3D PIM die, or the like. Optionally, in some embodiments, HBIC device 250 can also include an interlayer 253 between first die stack 251 and second die stack 252.

As shown in FIG. 2E, HBIC device 250 can include a wire bonding 254 that can connect first die stack 251 with second die stack 252 and communicate data and instructions between first die stack 251 and second die stack 252. As shown in FIG. 2E, wire bonding 254 can include a shared bus topology and a master-slave topology. For example, wire bonding 254 can include a bus, e.g., a bus 254-0, and a plurality of wire connections connected to the bus, e.g., wire connection 254-1 and wire connection 254-2. Bus 254-0 can connect at least one die of first die stack 251, e.g., die 251-1, to the plurality of wire connections e.g., wire connection 254-1 and wire connection 254-2. Wire connection 254-1 and wire connection 254-2 can connect bus 254-0 and thus die 251-1 to die 252-1 and die 252-2 of second die stack 252, respectively. Each connected die 252-1 or 252-2 of second die stack 252 can share bandwidth of bus 254-0, and communicate with die 251-1 of first die stack 251 through its corresponding wire connection 254-1 or 254-2 and bus 254-0. In addition, wire bonding 254 can also include a plurality of wire connections, e.g., wire connection 254-3, wire connection 254-4, . . . , and wire connection 254-N. Wire connection 254-3 can connect die 251-M of first die stack 251 to a master die 252-3 of second die stack 252. Wire connection 254-4, . . . , and wire connection 254-N can connect master die 252-3 to slave die 252-4, . . . , slave die 252-N, respectively. Master die 252-3 can communicate with die 251-M through wire connection 254-3, while slave die 252-4, . . . , slave die 252-N can communicate with master die 252-3 and indirectly communicate with die 251-M of first die stack 251. For example, in some embodiments, master die 252-3 is a logic die, and slave dies 252-4, . . . , 252-N are memory dies. Master logic die 252-3 can function as a controller that receives instructions or data from die 251-M of first die stack 251, and controls data or instruction access (e.g., read or write) to each of slave memory dies 252-4, . . . , 252-N. Master logic die 252-3 can also perform some computations with data from slave memory dies 252-4, . . . , 252-N, and output the computation result to die 251-M.

In some embodiments, wire connections 254-0 and 254-3 can be high-speed and high-bandwidth connections, while wire connections 254-1, 254-2, 254-4, . . . , 254-N can be relatively low-speed and low bandwidth connections.

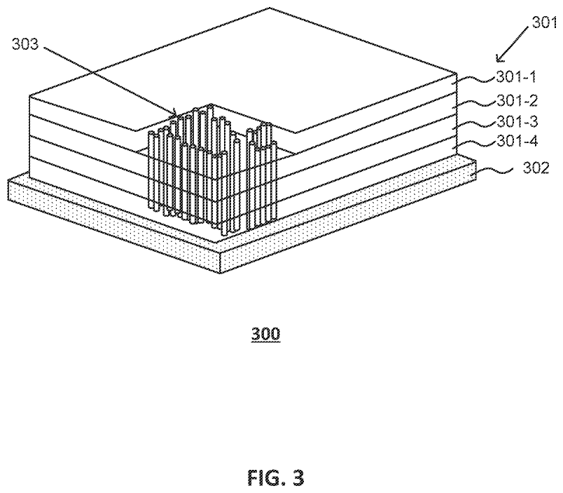

FIG. 3 is a schematic representation of an exemplary die stack 300, according to some embodiments of the present disclosure. It is appreciated that die stack 300 can be implemented in any of first die stack 101 and second die stack 102 of FIG. 1, first die stack 211 and second die stack 212 of FIG. 2A, first die stack 221 and second die stack 222 of FIG. 2B, first die stack 231 and second die stack 232 of FIG. 2C, first die stack 241 and second die stack 242 of FIG. 2D, first die stack 251 and second die stack 252 of FIG. 2E.

As shown in FIG. 3, die stack 300 can include a plurality of memory dies 301, e.g., memory die 301-1, memory die 301-2, memory die 301-3, memory die 301-4, and one or more logic die, e.g., logic die 302. The plurality of memory dies 301 can be stacked on a surface of logic die 302. Memory die 301-1, memory die 301-2, memory die 301-3, memory die 301-4, and logic die 302 can be back-to-face stacked one upon another. In some embodiments, the memory die can be a Dynamic Random Access Memory (DRAM) die, a Non-Volatile Memory (NVM) die, or the like. It can be appreciated that, die stack 300 can include a plurality of storage dies 301 (e.g., Flash dies) in addition to or instead of memory dies 301.

Die stack 300 can also include a plurality of TSVs 303 to provide connection among the plurality of memory dies 301 and logic die 302. TSVs 303 can communicate instructions and data among different dies. In some embodiments, TSVs 303 can go through all dies of die stack 300 to communicatively connect all memory dies and logic die (or logic dies) with each other. In some other embodiments, TSVs 303 can go through some dies of die stack 300 to connect a subset of dies with each other. TSVs can provide high-speed and high-bandwidth communication among different dies of die stack 300.

In some embodiments, logic die 302 can receive instructions or data from an outside component or device, such as a die of another die stack, a host unit, or the like, and control data or instruction access (e.g., read or write) to each of the plurality of memory dies 301. For example, logic die 302 can receive a read instruction of reading data from a particular memory die, such as from memory die 301-1. Logic die 302 can decode the instruction, and according to the decoded instruction, read the data from memory die 301-1. Then, logic die 302 can transmit the data outside.

In some embodiments, logic die 302 can also perform some computations with data from a memory die. For example, logic die 302 can read data from the memory die, such as memory die 301-3, and perform a computation on the data. In this case, die stack 300 can be a PIM device. The computation is performed on logic die 302 that is close to memory die 301-3 where the data actually resides. Therefore, performance can be improved and energy consumption can be reduced.

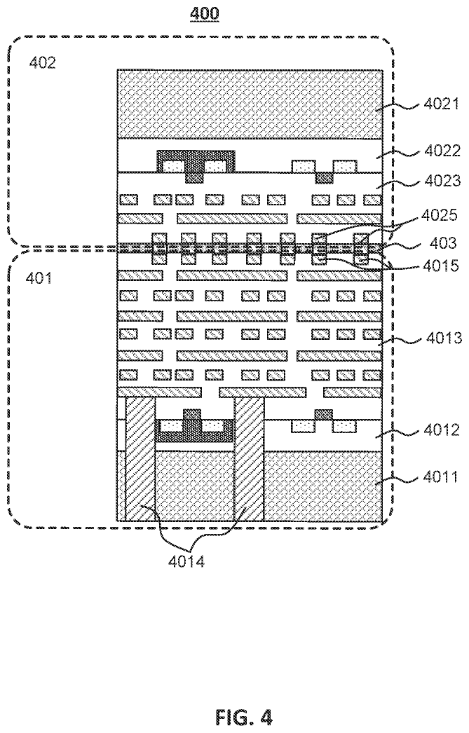

FIG. 4 is a schematic representation of another exemplary die stack 400, according to some embodiments of the present disclosure. It is appreciated that, die stack 400 can be implemented in any of first die stack 101 and second die stack 102 of FIG. 1, first die stack 211 and second die stack 212 of FIG. 2A, first die stack 221 and second die stack 222 of FIG. 2B, first die stack 231 and second die stack 232 of FIG. 2C, first die stack 241 and second die stack 242 of FIG. 2D, first die stack 251 and second die stack 252 of FIG. 2E.

As shown in FIG. 4, die stack 400 can include a logic die 401, a memory or storage die (hereinafter “memory die”) 402, and optionally an interlayer 403 between logic die 401 and memory die 402. Logic die 401 can include a substrate layer 4011, a device layer 4012, a metal layer 4013, and the like. Substrate layer 4011 can be formed by any suitable material, such as silicon, silicon carbide, or the like. Device layer 4012 can include one or more electronic components, such as transistors, or the like. Metal layer 4013 can include a plurality of metal traces or connections and multiple contacts 4015 that can protrude from an outer surface of the metal layer 4013. In some embodiments, logic die 401 can also include a plurality of TSVs 4014 that go through device layer 4012 and substrate 4011, and provide connection to outside devices. Logic die 401 can be manufactured by a logic process.

Similarly, memory die 402 can include a substrate layer 4021, a device layer 4022 and a metal layer 4023. In some embodiments, memory die 402 can be a DRAM die, an NVM die, a Flash die, or the like. Device layer 4022 can include one or more electronic components for storing data or instructions. Metal layer 4023 can include a plurality of metal connections and multiple contacts 4025 that can protrude from an outer surface of the metal layer 4023.

In some embodiments, logic die 401 can be integrated with memory die 402 in a face-to-face manner. As shown in FIG. 4, the outer surface of mental layer 4013 of logic die 401 faces that of metal layer 4023 of memory die 402. Contacts 4015 on the outer surface of mental layer 4013 can contact or be connected with contacts 4025 on the outer surface of mental layer 4023. Contacts 4015 and contacts 4025 can connect logic die 401 with memory die 402 and support a high-speed and high-bandwidth communication (e.g., instructions or data) therebetween.

Optionally, die stack 400 can also include an interlayer 403 between logic die 401 and memory die 402. In some embodiments, interlayer 403 can be formed by insulating material to insulate logic die 401 from memory die 402. Interlayer 403 can also include metal connections therein, such as TSVs, traces, or the like, to connect contacts 4015 with contacts 4025. In some embodiments, interlayer 403 can include adhesive material, such as polymer, to bond logic die 401 with memory die 402.

In some embodiments, logic die 401 can communicate with outside components or devices through such as TSVs 4014. For example, logic die 401 can receive instructions or data from an outside component, such as a die of another die stack, a host unit, or the like. Logic die 401 can control data or instruction access (e.g., read or write) to memory die 402. For example, logic die can decode the received instruction, and according to the decoded instruction, read data from memory die 402. Then, logic die 401 can transmit the data outside.

In some embodiments, logic die 401 can also perform some computations with data from memory die 402. For example, logic die 401 can read data from memory die 402 and perform a computation on the data. In this case, die stack 400 can be a PIM device. Since contacts 4015 and 4025 can provide communication with huge bandwidth and high speed, performance can be improved and energy consumption can be reduced.

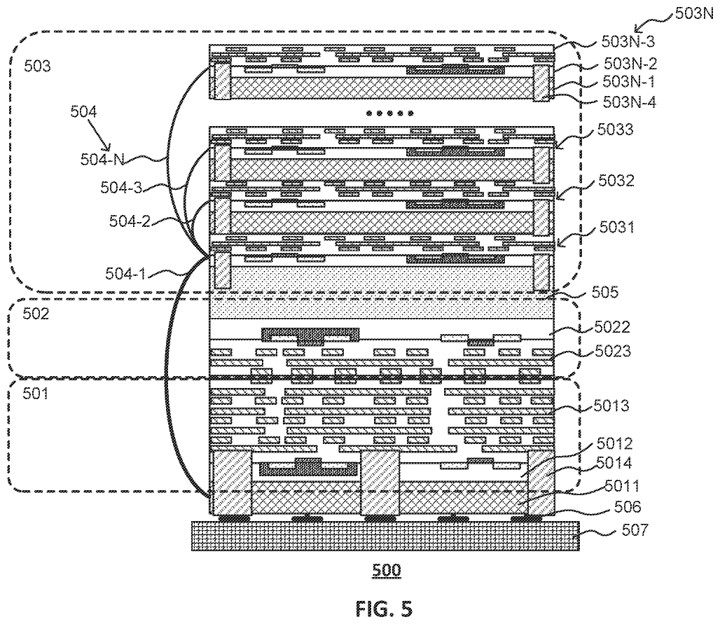

FIG. 5 is a schematic representation of an exemplary HBIC device 500 with memory dies, according to some embodiments of the present disclosure. It is appreciated that, die stack 500 can be implemented as any of HBIC device 100 of FIG. 1, HBIC device 210 of FIG. 2A, HBIC device 220 of FIG. 2B, HBIC device 230 of FIG. 2C, HBIC device 240 of FIG. 2D, or HBIC device 250 of FIG. 2E.

HBIC device 500 can include a first die stack (e.g., including logic die 501 and memory die 502), a second die stack 503, and optionally an interlayer 505. Similar to die stack 400 of FIG. 4, logic die 501 and memory die 502 of first die stack can integrated together in a face-to-face manner. Logic die 501 can be manufactured by a logic process. Memory die 502 can be a DRAM die, an NVM die, a Flash die, or the like. As shown in FIG. 5, logic die 501 can include a substrate layer 5011, a device layer 5012, a metal layer 5013, and the like. Memory die 502 can include a device layer 5022 and a metal layer 5023. Substrate layer 5011 can be formed by any suitable material, such as silicon, silicon carbide, or the like. Device layer 5012 or 5022 can include one or more electronic components, such as transistors, or the like. Metal layer 5013 or 5023 can include a plurality of metal traces or connections and multiple contacts on an outer surface of the metal layer 5013 or 5023. In some embodiments, logic die 501 can also include a plurality of TSVs 5014 that go through device layer 5012 and substrate 5011 and provide connection to outside devices. Contacts on the outer surface of mental layer 5013 can contact or be connected with contacts on the outer surface of mental layer 5023, supporting a high-speed and high-bandwidth communication (e.g., instructions or data) between logic die 501 with memory die 502. Although logic die 501 and memory die 502 are shown in face-to-face structure, it is appreciated that, first die stack can include a plurality of logic dies and a plurality of memory dies stacked together in other manner, such as back-to-face.

Second die stack 503 can be integrated on a surface of first die stack, e.g., on a back surface of memory die 502, with optional interlayer 505 provided therebetween. Second die stack 503 can include one or more memory dies, e.g., memory die 5031, memory die 5032, memory die 5033, . . . , memory die 503N, where N is equal to or larger than 1. It is appreciated that, the memory die can be a DRAM die, an NVM die, a Flash die, or the like. Each memory die, such as memory die 503N, can include a substrate layer 503N-1, a device layer 503N-2, a metal layer 503N-3, and the like. In some embodiments, memory die 5031, memory die 5032, memory die 5033, . . . , and memory die 503N can be back-to-face stacked one upon another. Each memory die can include one or more TSVs to connect with another die. For example, memory die 503N can include a plurality of TSVs 503N-4 to connect with another die 503(N−1) below memory die 503N. TSVs can provide high-speed and high-bandwidth communication among different memory dies of second die stack 503.

As shown in FIG. 5, HBIC device 500 can also include a wire bonding 504. Wire bonding 504 can connect first die stack with second die stack 503 and then, communicate data and instructions therebetween. Wire bonding 504 can include one or more wire connections in various topologies, such as single connection topology, bus topology, master-slave topology, multi-drop topology, a combination thereof, or the like. For example, as shown in FIG. 5, wire bonding 504 can include a plurality of wire connections, e.g., wire connection 504-1, wire connection 504-2, wire connection 504-3, . . . , wire connection 504-N. Wire connection 504-1 can connect at least one die of first die stack (e.g., logic die 501) to a master die 5031 of second die stack 503. Wire connection 504-2, wire connection 504-3, . . . , wire connection 504-N can connect master die 5031 to slave die 5032, slave die 5033, . . . , slave die 503N, respectively. In some embodiments, wire connection 504-1 to the master die 5031 can be a high-speed and high-bandwidth connection, while wire connections 504-2, 504-3, . . . , 504-N can be relatively low-speed and low bandwidth connections.

Optionally, HBIC device 500 can include a plurality of contacts 506 on substrate 5011 of logic die 501 and an interposer or package substrate 507. The contacts 506 can be connected with TSVs 5014 of logic die 501. With the contacts 506, the first die stack and second die stack are provided on interposer 507. Interposer 507 can include connections therein to connect the first die stack with outside components or devices. Logic die 501 can communicate data or instruction with outside through contacts 506.

In some embodiments, logic die 501 can control data or instruction access (e.g., read or write) to memory die 502 (or “near memory”), memory die 5031, memory die 5032, memory die 5033, . . . , and memory die 503N (or collectively “far memory”). For example, logic die 501 can include one or more near memory or storage controllers (hereinafter “near memory controller”). A near memory controller can control access to memory die 502. The near memory controller can read data or instructions from or write data or instruction to memory die 502 through a communication way including metal layer 5013, face-to-face integration, and metal layer 5023. The communication way can provide large bandwidth and high-speed access. Therefore, near memory controller can read or write data or instructions very fast from or to near memory 502. Near memory controller can store data or instructions that are frequently-used, recently-used or currently-used into near memory 502. Additionally, logic die 501 can include one or more far memory or storage controllers (hereinafter “far memory controller”). A far memory controller can be connected to one or more far memories of second die stack 503 through wire bonding 504. Then, far memory controller can control access to connected far memories of second die stack 503. Compared to the communication way inside first die stack, wire bonding 504 can provide communication with relatively lower speed and smaller bandwidth. Thus, far memory controller can store data or instructions that are not frequently used into far memory.

In some embodiment, logic die 501 (e.g., near memory controller or far memory controller) can perform a data or instruction migration between far and near memories. For example, logic die 501 can migrate hot (e.g., frequently-used, recently-used, or to-be-used) data or instruction from far memory to near memory, or migrate cold (e.g., rarely-used) data or instruction from near memory to far memory. The migration can be performed automatically or under control of a software or of another device such as a host unit.

In some embodiments, logic die 501 can also perform some computations with data from a memory die. For example, logic die 501 can read data from the memory die, such as memory die 502 or a memory die of second die stack 503, and perform a computation on the data. In this case, die stack 500 can be a PIM device.

HBIC device 500 utilizes hybrid bonding, including, but not limited to, face-to-face integration, TSVs, wire bonding, or the like. HBIC device 500 can integrate logic die with near memory using fast and high-bandwidth connection (e.g., face-to-face, metal layer, TSVs) and with far memory using relatively slow and low-bandwidth connection (e.g., wire bonding 504). HBIC device 500 can also store different types (e.g., hot or cold) of data or instructions in near or far memories to improve efficiency of data access. Therefore, HBIC device 500 can provide possibility and flexibility of extending die stack in an easy way, improve performance and reduce energy consumption.

It is appreciated that, some embodiments of present disclosure, such as HBIC device 100 of FIG. 1, HBIC device 210 of FIG. 2A, HBIC device 220 of FIG. 2B, HBIC device 230 of FIG. 2C, HBIC device 240 of FIG. 2D, HBIC device 250 of FIG. 2E, die stack 300 of FIG. 3, die stack 400 of FIG. 4, and HBIC device 500 of FIG. 5, can be implemented in or integrated with any architecture, such as a central processing unit (CPU), a graphics processing unit (GPU), a field programmable gate array (FPGA), a neural network processing unit (NPU), a tensor processing unit (TPU), a database acceleration unit (DAU), an application-specific integrated circuit (ASIC), or the like. It is also appreciated that, some embodiments of present disclosure can be deployed to computing devices, including, but not limited to, a tablet, a computer, a copier, a digital camera, a smart phone, a control system, an automated teller machine, or the like.

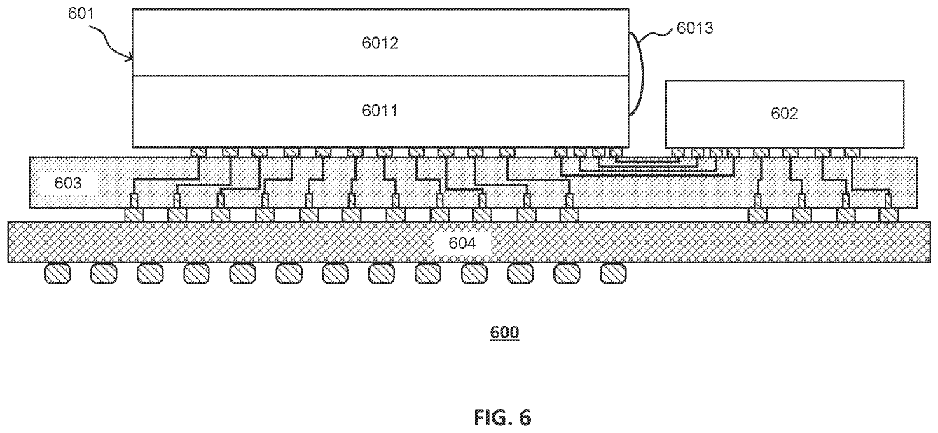

FIG. 6 is a schematic representation of an exemplary IC device 600, according to some embodiments of the present disclosure. As shown in FIG. 6, IC device 600 can include a HBIC device 601, a host device 602, and an interposer 603. It is appreciated that, HBIC device 601 can be any of HBIC device 100 of FIG. 1, HBIC device 210 of FIG. 2A, HBIC device 220 of FIG. 2B, HBIC device 230 of FIG. 2C, HBIC device 240 of FIG. 2D, HBIC device 250 of FIG. 2E, HBIC device 500 of FIG. 5, and the like. HBIC device 601 can include a first die stack 6011, a second die stack 6012, and a wire bonding 6013 communicatively connecting first die stack 6011 with second die stack 6012. First die stack 6011 can include one or more dies stacked together. Second die stack 6012 can be integrated on a surface of first die stack 6011, and include at least two dies stacked together.

Host unit 602 can be one or more processing units, such as CPU, GPU, System on Chip (SoC) die, or the like. Host unit 602 can be communicatively connected to HBIC device 601 by interposer 603. As shown in FIG. 6, interposer 603 can include a plurality of connections and contacts that can connect host unit 602 with HBIC device 601. Host unit 602 can send data or instructions to HBIC device 601. For example, host unit 602 can send a read instruction to HBIC device 601. According to the read instruction, HBIC device 601 can read data from a particular memory die, and output the data to host unit 602. In some embodiments, host unit 602 can control migration of data between far and near memories of HBIC device 601 under the control of host unit 602. In some embodiment, host unit 602 can send a computation instruction to HBIC device 601. According to the computation instruction, HBIC device 601 can read data from memory die, perform a particular computation on the data, and output a result of the computation to host unit 602.

Optionally, IC device 600 can also include a package substrate 604. Interposer 603 can connect HBIC device 601 and host unit 602 to package substrate 604. Then, package substrate 604 can connect to outside components or devices.

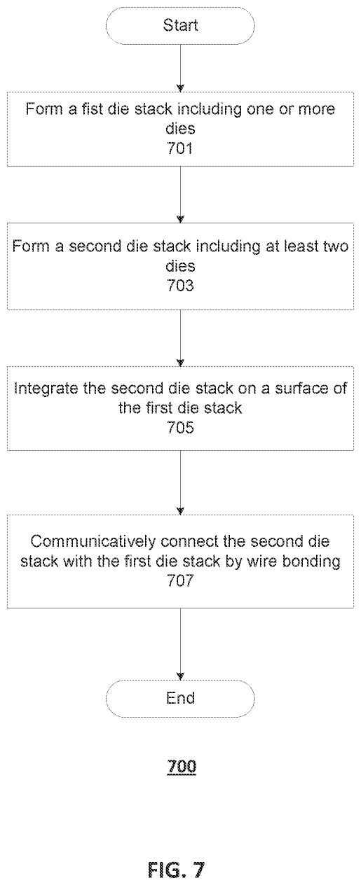

FIG. 7 is a flowchart of an exemplary method 700 for manufacturing a HBIC device, according to some embodiments of the present disclosure. The HBIC device can be any of HBIC device 100 of FIG. 1, HBIC device 210 of FIG. 2A, HBIC device 220 of FIG. 2B, HBIC device 230 of FIG. 2C, HBIC device 240 of FIG. 2D, HBIC device 250 of FIG. 2E, HBIC device 500 of FIG. 5, HBIC device 601 of FIG. 6, and the like.

At step 701, as shown in FIG. 7, a first die stack can be formed. First die stack can include one or more dies. In some embodiments, forming first die stack can include forming two or more dies and integrating the dies one on another.

At step 703, a second die stack can be formed. Second die stack can include at least two dies. Forming second die stack can include forming at least two dies and integrating the dies one on another.

In some embodiments, integration at step 701 or step 703 can include integrating two dies of first or second die stack in a face-to-face manner. In some embodiments, integration at step 701 or step 703 can include integrating two or more dies of first or second die stack in a back-to-face manner. In some embodiments, integration at step 701 or step 703 can include forming at least one of TSV, contact, metal layer, and NoC to connect two or more dies of first or second die stack.

It is appreciated that the die in first die stack or second die stack can be any type of dies, including, but not limited to, logic die, memory die, storage die, PIM die, or a combination thereof. Additionally, the die in first die stack or second die stack can be any two-dimensional (2D) die, e.g., 2D logic die, 2D memory die, 2D storage die, 2D PIM die, or the like, or any three-dimensional (3D) die, e.g., 3D silicon in chip (SiC), monolithic 3D ICs, or the like.

At step 705, second die stack can be integrated on a surface of first die stack. This integration can include forming an interlayer between first die stack and second die stack. In some embodiments, this integration can include forming an interlayer on the surface of first die stack and provide second die stack on the interlayer. The interlayer can bond the second die stack with first die stack.

At step 707, second die stack can be communicatively connected with first die stack by wire bonding. The connecting can include forming one or more wire connections in various topologies, such as single connection topology, bus topology, master-slave topology, multi-drop topology, or a combination thereof. For example, the connecting can include connecting one die of second die stack with one or more other dies of second die stack and forming a connection from first die stack to the one die. As another example, the connecting can include forming a connection from first die stack to a master die of second die stack and forming connections from the master die to one or more slave dies of second die stack. As another example, the connecting can include forming a plurality of connections from first die stack to one or more dies of second die stack in a multi-drop way. As another example, the connecting can include forming a bus from first die stack to second die stack, and forming a plurality of connections from the bus to one or more dies of second die stack.

Embodiments of the present disclosure can bring many technical advantages. For example, in some embodiments, HBIC device utilizes hybrid bonding that communicatively connects two or more die stacks with wire bonding. With wire bonding, HBIC device can be easily extended to include more dies or more die stacks.

In some embodiments, HBIC device can integrate logic die with near memory using fast and high-bandwidth connection (e.g., face-to-face, metal layer, TSVs) within die stack, and with far memory using relatively slow and low-bandwidth connection (e.g., wire bonding) across die stacks. HBIC device can also store hot data or instructions in near memories and cold data or instructions in far memories. This can significantly increase the overall memory space of the HBIC device while maintaining high efficiency of data access.

In some embodiments, HBIC device can be a PIM device. The computation can be performed on a logic die that is close to memory dies where the data actually resides. Therefore, performance can be improved and energy consumption can be reduced.

Embodiments of the present disclosure can be applied to many products, environments, and scenarios. For example, some embodiments of the present disclosure can be applied to Ali-NPU (e.g., Hanguang NPU), Ali-Cloud, Ali PIM-AI (PIM for AI), Ali-DAU, Ali-AI platform, GPU, TPU, or the like.

The embodiments may further be described using the following clauses:

1. A hybrid bonding based integrated circuit (HBIC) device, comprising:
a first die stack comprising one or more dies; and
a second die stack comprising at least two dies, the second die stack being integrated on a surface of the first die stack and communicatively connected to the first die stack by wire bonding.

2. The HBIC device of clause 1, wherein the wire bonding comprises:
a connection communicatively connecting the first die stack to a first die of the second die stack, wherein one or more dies of the second die stack is communicatively connected to the first die with through-silicon vias (TSVs).

3. The HBIC device of any of clauses 1-2, wherein the wire bonding comprises:
a bus extending from the first die stack to the second die stack; and a plurality of connections, each connection communicatively connecting a die of the second die stack to the bus.

4. The HBIC device of any of clauses 1-3, wherein the wire bonding comprises:
a plurality of connections, one connection of the plurality of connections communicatively connecting the first die stack with a master die of the second die stack, and other connections of the plurality of connections communicatively connecting one or more slave dies of the second die stack with the master die.

5. The HBIC device of any of clauses 1-4, wherein the wire bonding comprises:
a plurality of connections communicatively connecting the first die stack with two or more dies of the second die stack in a multi-drop way.

6. The HBIC device of any of clauses 1-5, wherein the first die stack or the second die stack comprises one or more logic dies, one or more memory dies, one or more storage dies, one or more process-in-memory (PIM) dies, or a combination thereof.

7. The HBIC device of any of clauses 1-6, wherein the first die stack or the second die stack comprises dies integrated in a manner of face to face, back to face, or a combination thereof.

8. The HBIC device of any of clauses 1-7, wherein the first die stack comprises: one or more memory dies or storage dies; and one or more logic dies, at least one of the one or more logic dies comprising a near memory controller to control at least one of the one or more memory dies or storage dies.

9. The HBIC device of clause 8, wherein the second die stack comprises one or more memory dies or storage dies, and wherein at least one of the one or more logic dies comprises a far memory controller to control at least one of the one or more memory dies or storage dies of the second die stack.

10. The HBIC device of clause 8 or clause 9, wherein the near memory controller or the far memory controller migrate frequently-used, recently-used, or to-be-used data or instructions from the one or more memory dies or storage dies of the second die stack to the one or more memory dies or storage dies of the first die stack, or migrate rarely-used data or instructions from the one or more memory dies or storage dies of the first die stack to the one or more memory dies or storage dies of the second die stack.

11. A method of manufacturing a hybrid bonding based integrated circuit (HBIC) device, comprising:
forming a first die stack comprising one or more dies;
forming a second die stack comprising at least two dies;
integrating the second die stack on a surface of the first die stack; and
communicatively connecting the second die stack with the first die stack by wire bonding.

12. The method of clause 11, wherein forming the first die stack or forming the second die stack comprises:
forming two or more dies; and
integrating the dies one on another in a manner of face to face, back to face, or a combination thereof.

13. The method of any of clauses 11-12, wherein the first die stack or the second die stack comprises one or more logic dies, one or more memory dies, one or more storage dies, one or more process-in-memory (PIM) dies, or a combination thereof.

14. The method of any of clauses 11-13, wherein integrating the second die stack on a surface of the first die stack comprises:
forming an interlayer on the surface of the first die stack; and
providing the second die stack on the interlayer.

15. The method of any of clauses 11-14, wherein communicatively connecting the second die stack with the first die stack by wire bonding comprises:
forming one or more wire connections in a single connection topology, a bus topology, master-slave topology, multi-drop topology, or a combination thereof.

16. The method of clause 15, wherein communicatively connecting the second die stack with the first die stack by wire bonding comprises:
communicatively connecting a first die of the second die stack with one or more other dies of the second die stack; and
forming a connection from the first die stack to the first die.

17. The method of clause 15 or clause 16, wherein communicatively connecting the second die stack with the first die stack by wire bonding comprises:
forming a connection from the first die stack to a master die of the second die stack; and
forming a plurality of connections from the master die to one or more slave dies of the second die stack.

18. The method of any of clauses 15-17, wherein communicatively connecting the second die stack with the first die stack by wire bonding comprises:
forming a plurality of connections from the first die stack to one or more dies of the second die stack in a multi-drop way.

19. The method of any of clauses 15-18, wherein communicatively connecting the second die stack with the first die stack by wire bonding comprises:
forming a bus from the first die stack to the second die stack; and
forming a plurality of connections from the bus to one or more dies of second die stack.

20. A terminal, comprising:
a host unit; and
a hybrid bonding based integrated circuit (HBIC) device communicatively coupled with the host unit, the HBIC device comprising:
   a first die stack comprising one or more dies; and
   a second die stack comprising at least two dies, the second die stack being integrated on a surface of the first die stack and communicatively connected to the first die stack by wire bonding.

21. The terminal of clause 20, wherein the wire bonding comprises:
a connection communicatively connecting the first die stack to a first die of the second die stack, wherein one or more dies of the second die stack is communicatively connected to the first die with through-silicon vias (TSVs).

22. The terminal of any of clauses 20-21, wherein the wire bonding comprises:
a bus extending from the first die stack to the second die stack; and
a plurality of connections, each connection communicatively connecting a die of the second die stack to the bus.

23. The terminal of any of clauses 20-22, wherein the wire bonding comprises:
a plurality of connections, one connection of the plurality of connections communicatively connecting the first die stack with a master die of the second die stack, and other connections of the plurality of connections communicatively connecting one or more slave dies of the second die stack with the master die.

24. The terminal of any of clauses 20-23, wherein the wire bonding comprises:
a plurality of connections communicatively connecting the first die stack with two or more dies of the second die stack in a multi-drop way.

25. The terminal of any of clauses 20-24, wherein the first die stack or the second die stack comprises one or more logic dies, one or more memory dies, one or more storage dies, one or more process-in-memory (PIM) dies, or a combination thereof.

26. The terminal of any of clauses 20-25, wherein the first die stack or the second die stack comprises dies integrated in a manner of face to face, back to face, or a combination thereof.

27. The terminal of any of clauses 20-26, wherein the first die stack comprises:
one or more memory dies or storage dies; and
one or more logic dies, at least one of the one or more logic dies comprising a near memory controller to control at least one of the one or more memory dies or storage dies.

28. The terminal of clause 27, wherein the second die stack comprises one or more memory dies or storage dies, and wherein at least one of the one or more logic dies comprises a far memory controller to control at least one of the one or more memory dies or storage dies of the second die stack.

29. The terminal of clause 27 or clause 28, wherein the near memory controller or the far memory controller migrate frequently-used, recently-used, or to-be-used data or instructions from the one or more memory dies or storage dies of the second die stack to the one or more memory dies or storage dies of the first die stack, or migrate rarely-used data or instructions from the one or more memory dies or storage dies of the first die stack to the one or more memory dies or storage dies of the second die stack.

The foregoing description has been presented for purposes of illustration. It is not exhaustive and is not limited to precise forms or embodiments disclosed. Modifications and adaptations of the embodiments will be apparent from consideration of the specification and practice of the disclosed embodiments. In addition, while certain components have been described as being coupled to one another, such components may be integrated with one another or distributed in any suitable fashion.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and are not limited to examples described in the present specification or during the prosecution of the application, which examples are to be construed as nonexclusive. Further, the steps of the disclosed methods can be modified in any manner, including reordering steps and/or inserting or deleting steps.

The features and advantages of the present disclosure are apparent from the detailed specification, and thus, it is intended that the appended claims cover all systems and methods falling within the true spirit and scope of the present disclosure. As used herein, the indefinite articles “a” and “an” mean “one or more.” Further, since numerous modifications and variations will readily occur from studying the present disclosure, it is not desired to limit the present disclosure to the exact construction and operation illustrated and described, and accordingly, all suitable modifications and equivalents may be resorted to, falling within the scope of the present disclosure.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Other embodiments will be apparent from consideration of the specification and practice of the embodiments disclosed herein. It is intended that the specification and examples be considered as example only, with a true scope and spirit of the disclosed embodiments being indicated by the following claims.

What is claimed is:

1. A hybrid bonding based integrated circuit (HBIC) device, comprising:
a first die stack comprising one or more dies; and
a second die stack integrated above the first die stack, the second die stack comprising at least two memory dies communicatively connected to the first die stack by wire bonding.

2. The HBIC device of claim 1, wherein the wire bonding comprises:
a connection communicatively connecting a die of the first die stack to a first die of the second die stack, wherein the at least two memory dies of the second die stack are communicatively connected with each other and to the first die with through-silicon vias (TSVs).

3. The HBIC device of claim 1, wherein the wire bonding comprises:
a bus extending from a die of the first die stack to the second die stack; and
a plurality of connections, each connection communicatively connecting a memory die of the second die stack to the bus.

4. The HBIC device of claim 1, wherein the wire bonding comprises:
a plurality of connections, one connection of the plurality of connections communicatively connecting a die of the first die stack with a master die of the second die stack, and other connections of the plurality of connections communicatively connecting one or more slave memory dies of the second die stack with the master die.

5. The HBIC device of claim 1, wherein the wire bonding comprises:
a plurality of connections communicatively connecting a die of the first die stack with two or more memory dies of the second die stack in a multi-drop way.

6. The HBIC device of claim 1, wherein the first die stack comprises one or more logic dies, one or more memory dies, one or more storage dies, one or more process-in-memory (PIM) dies, or a combination thereof.

7. The HBIC device of claim 1, wherein the second die stack further comprises one or more logic dies, one or more storage dies, one or more process-in-memory (PIM) dies, or a combination thereof.

8. The HBIC device of claim 1, wherein the first die stack or the second die stack comprises dies integrated in a manner of face to face, back to face, or a combination thereof.

9. The HBIC device of claim 1, wherein the first die stack comprises:
one or more memory dies; and
one or more logic dies, at least one of the one or more logic dies comprising a near memory controller to control at least one of the one or more memory dies,
wherein at least one of the one or more logic dies comprises a far memory controller to control at least one of the at least two memory dies of the second die stack.

10. The HBIC device of claim 9, wherein the near memory controller or the far memory controller migrate frequently-used, recently-used, or to-be-used data or instructions from the at least two memory dies of the second die stack to the one or more memory dies of the first die stack, or migrate rarely-used data or instructions from the one or more memory dies of the first die stack to the at least two memory dies of the second die stack.

11. A method of manufacturing a hybrid bonding based integrated circuit (HBIC) device, comprising:
forming a first die stack comprising one or more dies;
forming a second die stack comprising at least two memory dies;
integrating the second die stack above the first die stack; and
communicatively connecting the at least two memory dies of the second die stack with a die of the first die stack by wire bonding.

12. The method of claim 11, wherein forming the first die stack or forming the second die stack comprises:
forming two or more dies; and
integrating the dies one on another in a manner of face to face, back to face, or a combination thereof.

13. The method of claim 11, wherein the first die stack comprises one or more logic dies, one or more memory dies, one or more storage dies, one or more process-in-memory (PIM) dies, or a combination thereof.

14. The method of claim 11, wherein the second die stack further comprises one or more logic dies, one or more storage dies, one or more process-in-memory (PIM) dies, or a combination thereof.

15. The method of claim 11, wherein integrating the second die stack above the first die stack comprises:
forming an interlayer on the first die stack; and
providing the second die stack on the interlayer.

16. The method of claim 11, wherein communicatively connecting the at least two memory dies of the second die stack with the die of the first die stack by wire bonding comprises:
communicatively connecting a first die of the second die stack with one or more memory dies of the second die stack; and
forming a connection from the die of the first die stack to the first die.

17. The method of claim 11, wherein communicatively connecting the at least two memory dies of the second die stack with the die of the first die stack by wire bonding comprises:
forming a connection from the die of the first die stack to a master die of the second die stack; and
forming a plurality of connections from the master die to one or more slave memory dies of the second die stack.

18. The method of claim 11, wherein communicatively connecting the at least two memory dies of the second die stack with the die of the first die stack by wire bonding comprises:
forming a plurality of connections from the die of the first die stack to the at least two memory dies of the second die stack in a multi-drop way.

19. The method of claim 11, wherein communicatively connecting the at least two memory dies of the second die stack with the die of the first die stack by wire bonding comprises:
forming a bus from the die of the first die stack to the second die stack; and
forming a plurality of connections from the bus to the at least two memory dies of second die stack.

20. A terminal, comprising:
a host unit; and
a hybrid bonding based integrated circuit (HBIC) device communicatively coupled with the host unit, the HBIC device comprising:
a first die stack comprising one or more dies; and
a second die stack integrated above the first die stack, the second die stack comprising at least two memory dies communicatively connected to the first die stack by wire bonding.
